(19) United States
(12) Patent Application Publication
(10) Pub. No.: US 2006/0002573 A1
(43) Pub. Date: Jan. 5, 2006

(54) Radio receiver volume control system

(76) Inventors: Kevin Dale, Bucks (GB); Colin Crawford, Hereford (GB)

Correspondence Address: FLYNN THIEL BOUTELL & TANIS, P.C., 2026 RAMBLING ROAD, KALAMAZOO, MI, 49008-1631, US

(21) Appl. No.: 11/111,502

(22) Filed: Apr. 21, 2005

(30) Foreign Application Priority Data
Apr. 21, 2004 (GB) 0408875.3

(51) Int. Cl. H03G 3/00

(52) U.S. Cl. 381/104

(57) ABSTRACT

A method and system for adjusting the audio volume of an electronic device such as a digital audio broadcast radio receiver is described. The gain of an amplifier is adjusted according to additional data received with the signal, preferably a radio signal, so that the output volume level of a channel can be automatically adjusted.

This invention relates to a method for adjusting the volume levels of radio broadcasts in radio receiver systems.

Radio receiver systems for automotive audio systems in which volume adjustment is provided in response to the electromagnetic field strength of the channel at the receiver are well known. British patent application number 762922 describes a method of reducing the audio volume of the receiver if the radio channel field strength at the receiver is particularly weak. In such circumstances, high-power amplifiers are required to amplify the weak signal and this results in a large quantity of interference being heard by the user. In this case it is advantageous to reduce the volume of the received channel so that the interference reproduced by the loudspeaker system is never higher than a predetermined volume level.

More recently, U.S. Pat. No. 6,473,604 describes an automotive audio system in which the output volume level of the speaker system is adjusted according to the input level from various different input sources such as AM/FM tuners, cassette tape players or compact disc systems. This is achieved by first creating a reference output level from the CD, radio, or tape player by inputting a reference input signal to these sources. The input source offset is then based on the resulting reference output level. By measuring the output levels electronically, the offset to be applied to each source can be stored electronically and applied each time the source changes.

A problem not addressed by this document is that radio stations broadcast at different volume levels, so that changing between radio stations can result in an inaudible sound on one channel while a neighbouring channel may be too loud or quiet for the user.

Preferred embodiments of the present invention overcome these problems.

In accordance with the present invention there is provided a method for adjusting the audio volume of an audio electronic device comprising the steps of receiving a signal, receiving additional data associated with the signal, and adjusting the gain applied to an amplifier for the received signal in dependence on the received additional data.

Preferably, the electronic device is a digital audio broadcast radio receiver.

The embodiment disclosed here has the advantage that the output volume level of a received radio channel can be automatically adjusted according to a user's preferences regardless of the transmit volume level selected by the broadcaster. Additionally, a user can opt to have the output volume level of different radio channels at different levels based on user-stored preferences. Furthermore, different output volume levels can be selected from the stored user preferences for different programme types. Such an arrangement overcomes the problem of a large variation in output volume level associated with changing radio channels or the change in volume levels required by the user when listening to different radio programmes within the same channel.

An embodiment of the invention will now be described in detail by way of reference to the accompanying drawing, in which:

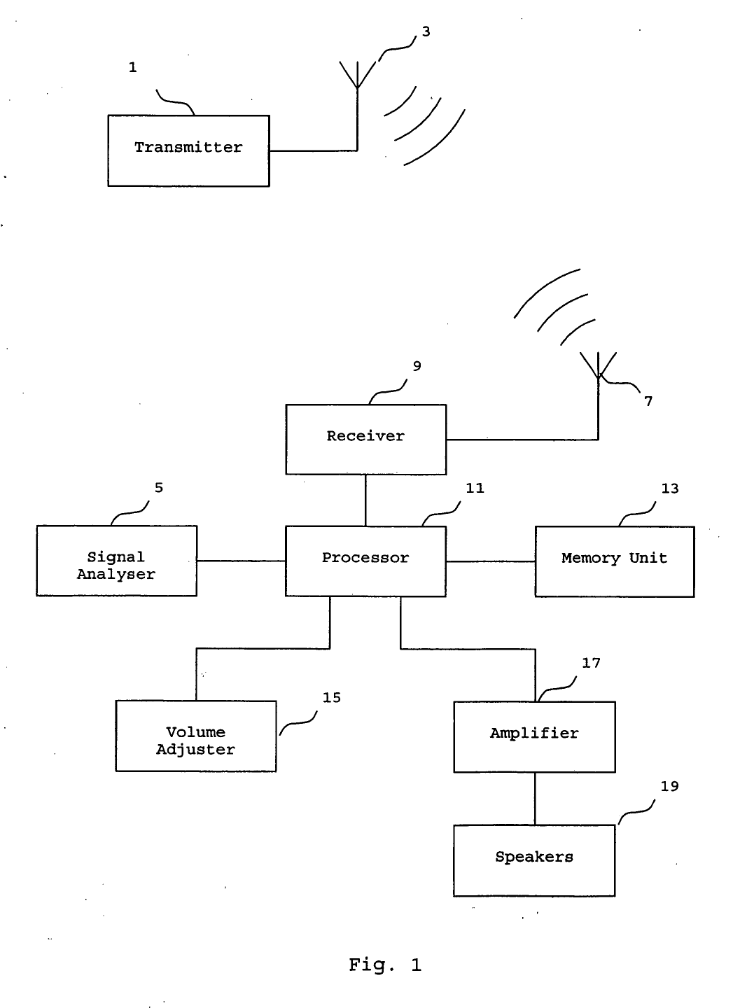

FIG. 1 shows a block diagram of apparatus embodying the invention.

Referring to FIG. 1, there is shown 1 a radio transmitter 1 and antenna 3 from which radio waves propagate and which are received by a user with an antenna 7 and receiver 9. A processor 11 then analyses the input signal and determines the source of the received signal. The determination of the source can be achieved in a variety of ways.

Preferably, the radio waves are broadcast using the Digital Audio Broadcast (DAB) digital radio service. Apart from usual advantages of digital technology, this service allows programme-associated data to be transmitted along with sound information. Such data can simply be text data indicating the current channel or can be other information relating to the current broadcast or a menu of future broadcasts. With this channel identifying information, the processor 11 can then access a memory unit 13 and retrieve appropriate level data stored in the memory unit 13. This level data is then used by the processor 18 to adjust the gain applied to an amplifier 17 for the signal so that an acceptable volume level is produced by from the speakers 19. In one embodiment substantially the same average value is produced for each channel.

In a further embodiment the Digital Audio Broadcast (DAB) digital radio service can be used to send information relating to the broadcast e.g. the broadcast level of a particular channel or even a particular programme can be included in the broadcast data. Such information allows the processor 11 to calculate the gain adjustment required so that the output volume level is maintained at a predetermined, possibly user determined level by adjusting the gain of the amplifier 17. The processor calculates the gain adjustment required and applies it to the amplifier so that the output volume level is maintained at the user preferred level, based on the data received from the broadcaster, and user preferences also stored in the memory unit. The gain adjustment can be such that the output volume of the channels is substantially the same level no matter what the broadcast level of the radio station or the channel selected by the user.

In a further embodiment the memory unit stores additional information relating to a user defined gain to be applied to each channel which may be different for each channel, in addition to the gain adjustment information that allows the user to change the channel and have the output level at a preferred default value for all channels. For example, some users may wish to listen to one channel quite loudly, while they may wish to listen to another channel rather more quietly. Accordingly, the user can vary the output volume of the channel according to the channel. In this case the user would program the radio receiver and store his volume preferences in the memory unit 13. Such an embodiment allows the user to change channels and allows him to listen to a variety of channels at his preferred different volume levels.

In yet a further embodiment, the user can store personal values in the memory unit relating to a desired volume level for different types of programme within the same channel. Such an embodiment works in a similar manner to the previous embodiment.

Preferably the user is able to select which of the methods of gain adjustment is to be applied by means of a selection device provided on the receiver and its processor.

The present invention is described with reference to a DAB radio receiver. However those skilled in the art will appreciate the applicability of the invention to conventional analogue radio on the VHF/FM wavebands. For these wavebands additional information (e.g. text information) can be transmitted to a receiver. This is achieved by using an encoder to inject a Radio Data System (RDS) message on the normal FM radio signal modulated just above the stereo audio signal. To receive the RDS message during the broadcast, the microprocessor-controlled tuner is retuned to receive the RDS data, during which the audio signal is muted. This operation occurs within a few mS and so the user is unaware of any break in the broadcast.

The RDS system allows programme service (PS) information to be encoded into the broadcast signal and detected by receivers where the name of the station currently tuned to can be read.

The processor can then adjust the gain and the output volume level based upon the programme service information, and the preferred values stored by the user during the set-up or by the manufacturer in the memory unit as described previously.

The RDS system also allows programme type information (PTY) whereby radio stations can assign different programme types to their shows e.g. NEWS, ROCK MUSIC, or CLASSICS. An embodiment of the invention as described above takes this text information and matches the text part to a corresponding text string used to look up information stored in the memory unit 13 relating to user preferences according to the type of programme. Then for example, if a user in a vehicle is listening to one type of programme at a background level, and the user has set the preferences that news programmes are to be turned up to a higher volume level, then the receiver will automatically adjust the gain to be applied according to the type of broadcast. A similar procedure could also be performed with traffic programme (TP) and traffic announcement (TA) data.

Alternatively, in this case, the channel volume broadcast offset information can be stored at the time of manufacture from information obtained from the broadcaster.

The present invention is described with reference to a radio receiver. However those skilled in the art will appreciate the applicability of the invention to other receiving equipment such as mobile phones, and televisual broadcasts. Additionally, the invention can also be used in a wide variety of electronic devices such as CD players, MP3 players, and mini disc players where an “average” volume field can be incorporated into the header information of the track so that the appropriate offset can be applied according to the track average volume level and to the user's preferences.

1. A method for adjusting the audio volume of an audio electronic device comprising the steps of:
receiving a signal;
receiving additional data associated with the signal; and
adjusting the gain applied to an amplifier for the received signal in dependence on the received additional data.

2. A method for adjusting the audio volume according to claim 1 in which the electronic device is a digital audio broadcast radio receiver.

3. A method for adjusting the audio volume according to claim 1 in which the electronic device is an analogue radio equipped with radio data system decoding.

4. A method according to claim 1 in which the step of adjusting the gain comprises the step of retrieving stored data relating to the received signal and deriving an adjustment from the gain of the amplifier from the stored data.

5. A method according to claim 1 in which the gain adjustment derived when applied to the amplifier produces substantially the same output level for each received signal.

6. A method according to claim 1 in which the gain adjustment is derived in dependence on a user defined volume preference for each received signal.

7. A method according to claim 1 in which the gain adjustment is derived in dependence on programme data received in the additional information associated with the received signal.

8. A method according to claim 4 in which the user may select the method of gain adjustment.

9. A system for adjusting the audio volume of an audio electronic device comprising:
means for receiving a signal;
means for receiving additional data associated with the signal; and
means for adjusting the gain applied to an amplifier for the received signal in dependence on the received additional data.

10. A system for adjusting the audio volume according to claim 9 in which the electronic device is a digital audio broadcast radio receiver.

11. A system for adjusting the audio volume according to claim 9 in which the electronic device is an analogue radio equipped with radio data system decoding.
